(19) United States
(12) Patent Application Publication
(10) Pub. No.: US 2023/0115020 A1
(43) Pub. Date: Apr. 13, 2023

(54) MOTHER SUBSTRATE FOR DISPLAY PANEL AND METHOD OF MANUFACTURING DISPLAY PANEL

(71) Applicant: Samsung Display Co., LTD., Yongin-si (KR)

(72) Inventors: Wongeun LEE, Cheonan-si (KR); Junghwan BYUN, Cheonan-si (KR); Younggug SEOL, Cheonan-si (KR); Taejong EOM, Pyeongtaek-si (KR); Chungi YOU, Asan-si (KR)

(73) Assignee: Samsung Display Co., LTD., Yongin-si (KR)

(21) Appl. No.: 17/872,283

(22) Filed: Jul. 25, 2022

(30) Foreign Application Priority Data
Sep. 24, 2021 (KR) 10-2021-0126346

(51) Int. Cl. H04N 9/31; H05K 5/03

(52) U.S. Cl. CPC H04N 9/3141; H05K 5/03; H01L 27/3223

(57) ABSTRACT

A mother substrate for a display panel includes a first substrate including a panel area and a peripheral area surrounding at least one side of the panel area, a second substrate disposed on a first surface of the first substrate, a first support member disposed on a second surface of the first substrate opposite to the first surface of the first substrate in a first direction, the first support member overlapping the panel area of the first substrate in a plan view, and a second support member disposed on the second surface of the first substrate, the second support member overlapping the peripheral area of the first substrate in a plan view.

### CROSS-REFERENCE TO RELATED APPLICATION(S)

This application claims priority to and benefits of Korean Patent Application No. 10-2021-0126346 under 35 USC § 119, filed on Sep. 24, 2021, in the Korean Intellectual Property Office, the entire contents of which are incorporated herein by reference.

### BACKGROUND

### 1. Technical Field

Embodiments relate to a mother substrate for the display panel for manufacturing the display panel and a method of manufacturing the display panel using the same.

### 2. Description of the Related Art

A display panel may include a base substrate, a display structure for displaying an image on the base substrate, and an encapsulation substrate covering the display structure. When manufacturing the display panel, the display panel may be formed by first manufacturing a mother substrate for the display panel and then cutting the mother substrate for the display panel according to a preset area of the display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a mother substrate for a display panel that reduces the defect rate.

Embodiments provide a method of manufacturing the display panel using the mother substrate for the display panel.

A mother substrate for a display panel according to an embodiment may include a first substrate including a panel area and a peripheral area surrounding at least one side of the panel area, a second substrate disposed on a first surface of the first substrate, a first support member disposed on a second surface of the first substrate opposite to the first surface of the first substrate in a first direction, the first support member overlapping the panel area of the first substrate and a second support member disposed on the second surface of the first substrate and overlapping the peripheral area of the first substrate in a plan view.

In an embodiment, the first support member and the second support member may include a same material.

In an embodiment, the first support member and the second support member may include a reflective material.

In an embodiment, the mother substrate may further include a display structure disposed between the first substrate and the second substrate, the display structure overlapping the panel area in a plan view.

In an embodiment, the first support member may overlap the display structure on the first substrate in a plan view.

In an embodiment, the second support member may not overlap the display structure on the first substrate in a plan view.

In an embodiment, a length of the first support member in a second direction crossing the first direction may be greater than or substantially equal to a length of the display structure in the second direction.

In an embodiment, the second support member may be spaced apart from the first support member in a second direction that intersects the first direction.

In an embodiment, a length of the first support member in the second direction may be greater than a length of the second support member in the second direction.

In an embodiment, a thickness of the first support member in the first direction may be smaller than a thickness of the first substrate in the first direction.

In an embodiment, a thickness of the first support member in the first direction may be substantially equal to a thickness of the second support member in the first direction.

A method of manufacturing a display panel according to an embodiment may include forming a second substrate on a first surface of a first substrate, the first substrate including a first panel area and a first peripheral area surrounding at least one side of the first panel area, and the second substrate including a second panel area and a second peripheral area surrounding at least one side of the second panel area, forming a first support member on a second surface of the first substrate opposite to the first surface of the first substrate in a first direction, the first support member overlapping the first panel area of the first substrate in a plan view, forming a second support member on the second surface of the first substrate, the second support member overlapping the first peripheral area of the first substrate in a plan view, cutting the first substrate along a boundary between the first panel area and the first peripheral area, cutting the second substrate along a boundary between the second panel area and the second peripheral area, and removing a portion of the first substrate and a portion of the second substrate, the removed portion of the first substrate being disposed in the first peripheral area, and the removed portion of the second substrate being disposed in the second peripheral area.

In an embodiment, the first support member and the second support member may be formed simultaneously.

In an embodiment, the first support member and the second support member may include a reflective material.

In an embodiment, the removing of the portion of the first substrate and the portion of the second substrate disposed in the second peripheral area may include removing the second support member formed in the first peripheral area of the first substrate.

In an embodiment, the method may further include forming a display structure between the first substrate and the second substrate in the first panel area of the first substrate.

In an embodiment, the first support member that may be formed on the second surface of the first substrate may overlap the display structure in a plan view.

In an embodiment, the second support member that may be formed on the second surface of the first substrate may be spaced apart from the display structure in a plan view.

In an embodiment, the cutting of the first substrate may include cutting between a first portion of the first substrate overlapping the first support member and a second portion of the first substrate overlapping the second support member in a plan view, and the cutting of the second substrate may include cutting between a third portion of the second substrate overlapping the first support member in a plan view and a fourth portion of the second substrate overlapping the second support member in a plan view.

In an embodiment, the first panel area may overlap the second panel area in a plan view, and the first substrate and the second substrate may be respectively cut so that an area of the first panel area is greater than an area of the second panel area.

In a display device according to embodiments, the mother substrate for the display panel may include a first support member and a second support member. The first support member may support a portion of the first substrate disposed in the first panel area and a portion of the second substrate disposed in the second panel area. The second support member may support a portion of the first substrate disposed in a first peripheral area and a portion of the second substrate disposed in a second peripheral area.

When the mother substrate for the display panel is cut, a constant pressure may be applied to the entire mother substrate for the display panel due to the first support member and the second support member. Accordingly, the first support member and the second support member may prevent chipping, where cut edge portions of the first substrate and the second substrate is broken or stamped, from occurring.

The first support member may include a reflective material. The first support member may prevent light emitted from the display structure from being emitted through the first substrate.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a mother substrate for a display panel according to an embodiment.

FIG. 2 is a schematic cross-sectional view taken along line I-I' of FIG. 1.

FIG. 3 is an enlarged schematic view of area A of FIG. 2.

FIG. 4 is a schematic plan view illustrating another example of the mother substrate for the display panel of FIG. 1.

FIGS. 5 to 10 are schematic cross-sectional views illustrating a method of manufacturing a display panel according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

The same reference numerals are used for the same components in the drawings, and redundant descriptions of the same components will be omitted.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

“About,” “substantially,” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

It will be understood that when an element (or a region, a layer, a portion, or the like) is referred to as “being on,” “connected to,” or “coupled to” another element in the specification, it can be directly disposed on, connected, or coupled to another element mentioned above, or intervening elements may be disposed therebetween.

It will be understood that the terms “connected to” or “coupled to” may include a physical or electrical connection or coupling.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

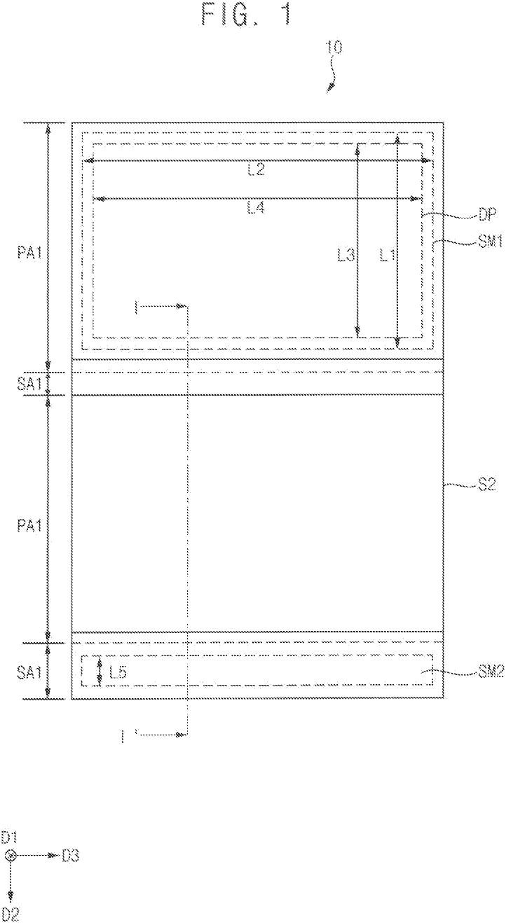

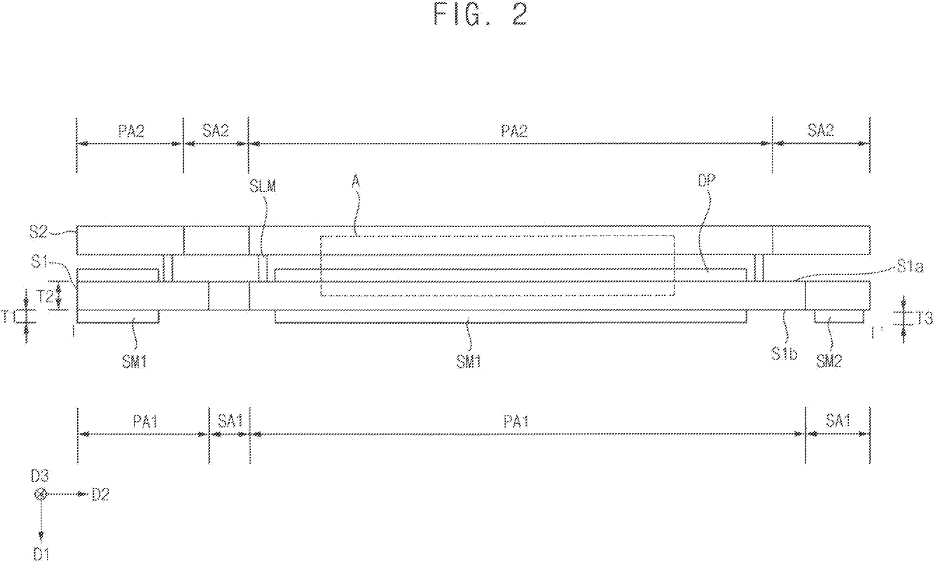

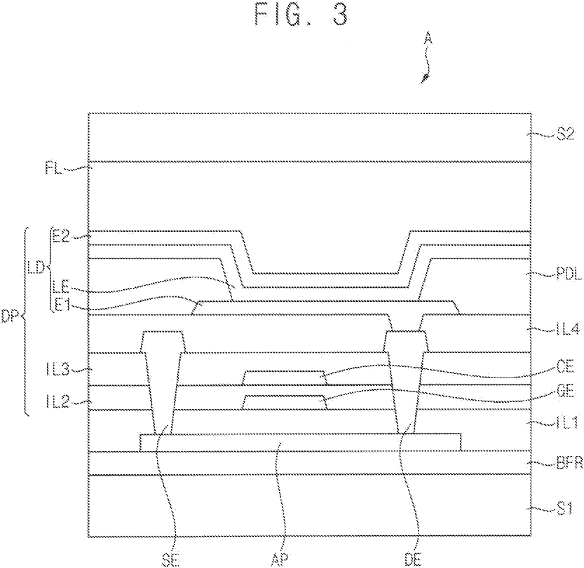

FIG. 1 is a schematic plan view of a mother substrate for a display panel according to an embodiment. FIG. 2 is a schematic cross-sectional view taken along a line I-I' of FIG. 1. FIG. 3 is an enlarged schematic view of area A of FIG. 2. For example, FIG. 3 may illustrate an internal structure of the display structure DP of FIG. 2.

In FIGS. 1 and 2, a mother substrate 10 for a display panel may include a first substrate S1, display structures DP, sealing members SLM, a second substrate S2, and first support members SM1 and second support members SM2.

The mother substrate 10 for the display panel may be used to form a display panel. Multiple display panels may be separated from the mother substrate 10 by cutting the mother substrate 10. For example, the mother substrate 10 for the display panel may form two display panels. However, the embodiments are not limited thereto, and the mother substrate 10 for the display panel may form one display panel, or three or more display panels.

Hereinafter, the mother substrate 10 for the display panel will be described as forming two display panels.

The first substrate S1 may include first panel areas PA1 and first peripheral areas SA1. Each of the first panel areas PA1 of the first substrate S1 may be an area in which the display structure DP is disposed, and may be an area used as a part of the display panel. Each of the first peripheral areas SA1 of the first substrate S1 may surround at least one side of each of the first panel areas PA1, an area in which the display structure DP is not disposed, and may be an area removed in a manufacturing process of the display panel.

The first substrate S1 may include a rigid material. For example, the first substrate S1 may be a glass substrate that includes glass.

The first panel areas PA1 and the first peripheral areas SA1 may be alternately disposed in a direction (e.g., a second direction D2). The first peripheral areas SA1 may have different areas from each other. For example, the first peripheral area SA1 positioned between the first panel areas PA1 may have an area smaller than the first peripheral area SA1 positioned at an end of the first substrate S1 in the second direction D2.

The display structures DP may be disposed on a first surface S1a of the first substrate S1. Each of the display structures DP may overlap the first panel area PA1 in a plan view and may emit light for displaying an image. The display structures DP may be disposed between the first substrate S1 and the second substrate S2.

Referring to FIG. 3, the display structure DP may include a buffer layer BFR, an active layer AP, a gate electrode GE, a capacitor electrode CE, a first insulation layer IL1, and a second insulation layer IL2, a third insulation layer IL3, a source electrode SE, a drain electrode DE, a fourth insulation layer IL4, a light emitting diode LD, and a pixel defining layer PDL. The light emitting diode LD may include a first electrode E1, a light emitting layer LE, and a second electrode E2.

The buffer layer BFR may be disposed on the first substrate S1, and may prevent penetration of foreign substances or moisture from the first substrate S1. The active layer AP may be disposed on the buffer layer BFR. The first insulation layer IL1 may cover the active layer AP and may be disposed on the buffer layer BFR.

The gate electrode GE may be disposed on the first insulation layer IL1. The second insulation layer IL2 may cover the gate electrode GE and may be disposed on the first insulation layer IL1. The capacitor electrode CE may be disposed on the second insulation layer IL2. The third insulation layer IL3 may cover the capacitor electrode CE and may be disposed on the second insulation layer IL2.

The source electrode SE and the drain electrode DE may be disposed on the third insulation layer IL3. Each of the source electrode SE and the drain electrode DE may be electrically connected to the active layer AP through contact holes penetrating the first insulation layer IL1, the second insulation layer IL2, and the third insulation layer IL3.

The fourth insulation layer IL4 may cover the source electrode SE and the drain electrode DE and may be disposed on the third insulation layer IL3.

The first electrode E1 may be disposed on the fourth insulation layer IL4. The first electrode E1 may be electrically connected to the source electrode SE or the drain electrode DE through a contact hole penetrating the fourth insulation layer IL4.

The light emitting layer LE may be disposed on the first electrode E1. The light emitting layer LE may include at least one of functional layers such as a hole injection layer, a hole transport layer, an organic light emitting layer, an electron transport layer, and an electron injection layer, and may have a single-layer or multi-layer structure.

The second electrode E2 may be disposed on the light emitting layer LE.

The pixel defining layer PDL may be disposed on the fourth insulation layer IL4. The pixel defining layer PDL may have an opening overlapping at least a portion of the first electrode E1 in a plan view. The light emitting layer LE may be disposed in the opening.

A filling layer FL may be disposed between the second electrode E2 and the second substrate S2. A thin film layer may be further disposed on the second electrode E2. However, the embodiments are not limited thereto, and the thin film layer may not be disposed on the second electrode E2.

Referring to FIGS. 1 and 2, the sealing members SLM may be disposed on the first substrate S1. The sealing members SLM may overlap the first panel area PA1 in a plan view and may be disposed around the display structure DP. The sealing members SLM may be disposed between the first substrate S1 and the second substrate S2, and the first substrate S1 and the second substrate S2 may be bonded through the sealing members SLM.

The second substrate S2 may be disposed on the display structures DP. The second substrate S2 may be disposed on the first substrate S1 and the sealing member SLM to cover the display structures DP. The second substrate S2 may protect the display structure DP from the outside.

Like the first substrate S1, the second substrate S2 may be a glass substrate including glass.

The second substrate S2 may include second panel areas PA2 and second peripheral areas SA2. Each of the second panel areas PA2 of the second substrate S2 overlaps the display structure DP in a plan view, and each may be an area used as a part of the display panel. Each of the second peripheral areas SA2 of the second substrate S2 may surround at least one side of each of the second panel areas PA2, may not overlap the display structure DP in a plan view. The second peripheral areas SA2 may be an area removed during the manufacturing process of the display panel.

The second panel areas PA2 and the second peripheral areas SA2 may be alternately positioned in a direction (e.g., the second direction D2). The first peripheral areas SA1 may have different areas from each other. For example, the second peripheral area SA2 positioned between the second panel areas PA2 may have an area smaller than the second peripheral area SA2 positioned at an end of the second substrate S2 in the second direction D2.

The first substrate S1 may be divided into the first panel areas PA1 and the first peripheral areas SA1, respectively, when the display panel is formed. Each of portions overlapping the first panel areas PA1 of the first substrate S1 may be a base substrate of each of the display panels. The second substrate S2 may be divided into the second panel areas PA2 and the second peripheral areas SA2, respectively, when the display panel is formed. Each of portions overlapping the second panel areas PA2 of the second substrate S2 may be an encapsulation substrate of each of the display panels.

The first panel area PA1 may overlap the second panel area PA2 in a plan view, and the first peripheral area SA1 may overlap the second peripheral area SA2 in a plan view.

The first panel area PA1 may have an area larger than the second panel area PA2, and the first peripheral area SA1 may have an area smaller than the second peripheral area SA2. A driving chip or a flexible circuit board may be electrically coupled to a portion of the first panel area PA1 of the first substrate S1 which is not covered by the second panel area PA2. However, embodiments are not limited thereto, and the first panel area PA1 may have an area substantially equal to the second panel area PA2.

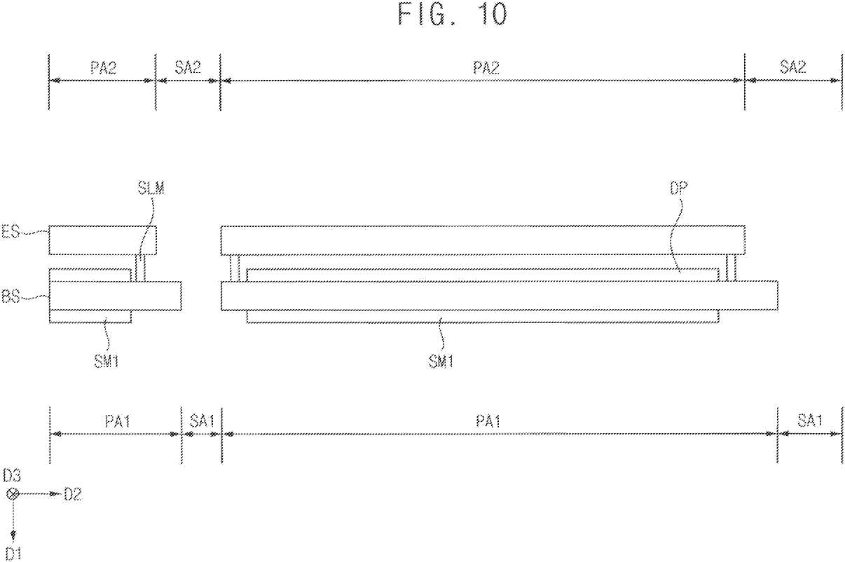

Accordingly, the base substrate (e.g., the base substrate BS of FIG. 10) of the first substrate S1 and the encapsulation substrate (e.g., the encapsulation substrate ES of FIG. 10) of the second substrate S2 may form the display panel. A portion of the first substrate S1 positioned in the first peripheral area SA1 and a portion of the second substrate S2 positioned in the second peripheral area SA2 may be removed.

The first support members SM1 may be disposed on a second surface S1b of the first substrate S1. The second surface S1b of the first substrate S1 may be opposite to the first surface S1a of the first substrate S1 in a first direction D1. The first support members SM1 may respectively overlap the first panel areas PA1 of the first substrate S1 in a plan view, and may respectively overlap the display structures DP in a plan view.

The second support member SM2 may be disposed on the second surface S1b of the first substrate S1. The second support member SM2 may overlap the first peripheral area SA1 of the first substrate S1 in a plan view, and may not overlap the display structures DP in a plan view.

For example, the second support member SM2 may be disposed in the first peripheral area SA1 positioned at an end of the first substrate S1 in the second direction D2. The second support member SM2 may support the first peripheral area SA1. The second support member SM2 may not be disposed in the first peripheral area SA1 disposed between the first panel areas PA1 of the first substrate S1. However, the embodiments are not limited thereto, and the second support member SM2 may also be disposed in the first peripheral area SA1 disposed between the first panel areas PA1.

The second support member SM2 may be spaced apart from the first support member SM1 in the second direction D2. The second direction D2 may intersect the first direction D1, and the second direction D2 may be a direction from the first panel area PA1 of the first substrate S1 to the first peripheral area SA1 adjacent to the first panel area PA1. However, the embodiments are not limited thereto, and the second support member SM2 may be disposed to be spaced apart from the first support member SM1 in a direction opposite to the second direction D2.

The first support member SM1 may include a reflective material. When the light emitted from the display structure DP is emitted in a direction to the first substrate S1, the first support member SM1 may reflect the light. Accordingly, the first support member SM1 may prevent the light emitted from the display structure DP from being emitted in the first direction D1. The light emitted from the display structure DP may display an image by being emitted in a direction from the display structure DP to the encapsulation substrate of the display panel (e.g., in a direction opposite to the first direction D1). When the light emitted from the display structure DP is emitted in the first direction D1, a luminance of the display panel may be lowered, and thus display quality may be lowered. The first support member SM1 may include the reflective material, and the first support member SM1 may reflect the light emitted from the display structure DP in a direction from the display structure DP to the encapsulation substrate. Accordingly, an intensity of the light emitted from the display structure DP may be maintained. The luminance of the display panel may not be decreased.

The first support member SM1 may be disposed on the second surface S1b of the first substrate S1. The first support member SM1 may protect the first substrate S1. For example, the first substrate S1 may not directly contact the stage due to the first support member SM1. Accordingly, the first support member SM1 may protect the display panel from external damage in the manufacturing process of the display panel.

The second support member SM2 may be formed using the same material as the first support member SM1. Accordingly, the second support member SM2 may include the reflective material. The first support member SM1 and the second support member SM2 may be formed of the same material in a same process. Accordingly, an additional process may not be required when manufacturing the display panel.

In an embodiment, a length L1 of the first support member SM1 in the second direction D2 may be greater than a length L3 of the display structure DP in the second direction D2. A length L2 of the first support member SM1 in the third direction D3 may be greater than a length L4 of the display structure DP in the third direction D3. In other examples, a length L1 of the first support member SM1 in the second direction D2 may be substantially equal to a length L3 of the display structure DP in the second direction D2. The length L2 of the first support member SM1 in the third direction D3 may be substantially equal to the length L4 of the display structure DP in the third direction D3. The third direction D3 may intersect the second direction D2 and the first direction D1. For example, the first support member SM1 may overlap the entire display structure DP in a plan view, and an area of the first support member SM1 may be greater than or equal to an area of the display structure DP.

When the length L1 of the first support member SM1 in the second direction D2 is smaller than the length L3 of the display structure DP in the second direction D2, and the length L2 of the first support member SM1 in the third direction D3 is smaller than the length L4 of the display structure DP in the third direction D3, the light emitted from the display structure DP may be emitted in the first direction D1 through a portion of the first substrate S1 which does not overlap the first support member SM1. Accordingly, the luminance of the display panel may be lowered, and display quality may be lowered.

A thickness T1 of the first support member SM1 in the first direction D1 may be smaller than a thickness T2 of the first substrate S1 in the first direction D1. When the thickness T1 of the first support member SM1 in the first direction D1 is greater than the thickness T2 of the first substrate S1 in the first direction D1, a thickness of the display panel may increase due to the first support member SM1. Accordingly, portability of a display device including the display panel may be reduced.

The length L1 of the first support member SM1 in the second direction D2 may be greater than a length L5 of the second support member SM2 in the second direction D2. A length of the first panel area PA1 included in the first substrate S1 in the second direction D2 may be greater than a length of the first peripheral area SA1 included in the first substrate S1 in order to minimize a removed area to use the mother substrate 10 for display panel efficiently. Accordingly, the length L1 of the first support member SM1 in the second direction D2 overlapping the first panel area PA1 of the first substrate S1 may be greater than the length L5 of the second support member SM2 overlapping with the first peripheral area SA1 in the second direction D2.

For example, when the length L1 of the first substrate S1 in the second direction D2 is smaller than the length L5 of the second support member SM2 in the second direction D2, an area of the mother substrate 10 for the display panel used for forming the display panel may be reduced, and a removed area may be increased. Accordingly, manufacturing efficiency of the display panel may be decreased.

The thickness T1 of the first support member SM1 in the first direction D1 may be substantially equal to a thickness T3 of the second support member SM2 in the first direction D1. Since the first support member SM1 and the second support member SM2 are formed of the same material in the same process, the thickness T1 of the first support member SM1 and the thickness T3 of the second support member SM2 may be substantially equal to each other. When the thickness T1 of the first support member SM1 and the thickness T3 of the second support member SM2 are different from each other, an additional processes may be required since the first support member SM1 and the second support member SM2 must be formed in different ways.

In an embodiment, the first support member SM1 may include the reflective material and overlap the entire display structure DP in a plan view, so that the light emitted from the display structure DP may be prevented from being emitted in the first direction D1.

In an embodiment, the first support member SM1 and the second support member SM2 may be disposed on the second surface S1b of the first substrate S1, and the first support member SM1 may overlap the first panel area PA1 of the first substrate S1 in a plan view, and the second support member SM2 may overlap, in a plan view, the first peripheral area SA1 positioned at an end of the first substrate S1. The first support member SM1 may support a portion of the first substrate S1 positioned in the first panel area PA1 and a portion of the second substrate S2 positioned in the second panel area PA2. The second support member SM2 may support a portion of the first substrate S1 positioned in the first peripheral area SA1 and a portion of the second substrate S2 positioned in the second peripheral area SA2.

When the display panel is formed by the mother substrate 10 for the display panel, the mother substrate 10 for the display panel may be cut. The first substrate S1 may be cut between the first panel area PA1 and the first peripheral area SA1 adjacent to the first panel area PA1, and the second substrate S2 may be cut between the second panel area PA2 and the second peripheral area SA2 adjacent to the second panel area PA2. When the mother substrate 10 for the display panel is cut, a constant pressure may be applied to the entire mother substrate 10 for the display panel due to the first support member SM1 and the second support member SM2. Accordingly, sagging in portions of the first substrate S1 and the second substrate S2 may not occur. The first support member SM1 and the second support member SM2 may prevent chipping, where cut edge portions of the first substrate S1 and the second substrate S2 may be broken or stamped, from occurring. Accordingly, manufacturing defects of the display panel may be prevented, and the strength of the display panel may be improved.

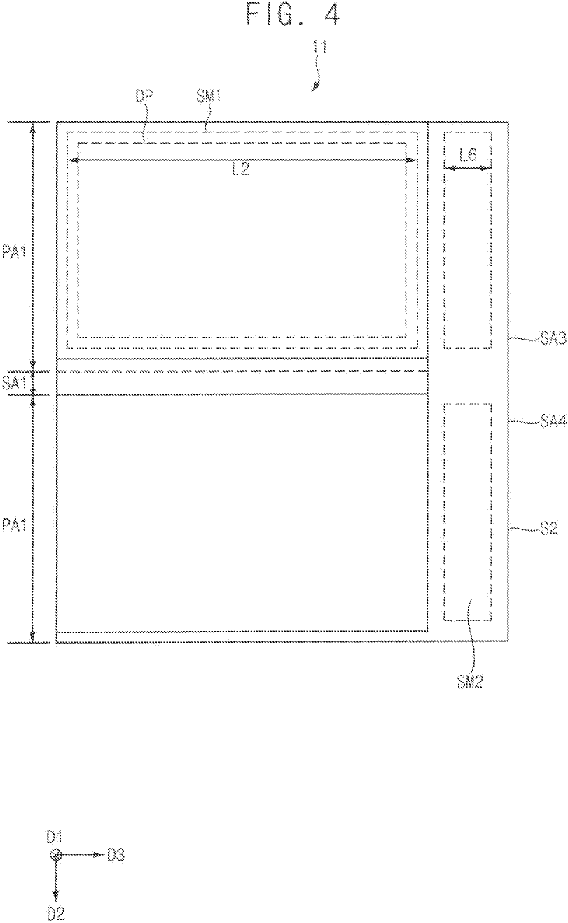

FIG. 4 is a schematic plan view illustrating another example of the mother substrate for the display panel of FIG. 1. A mother substrate 11 for a display panel of FIG. 4 may be substantially equal to the mother substrate 10 of FIG. 1, other than the arrangement of the second support members SM2 and the arrangement of the panel areas PA1 and PA2 and the peripheral areas SA1, SA2, SA3 and SA4. Accordingly, descriptions of elements and features already provided may be omitted below.

Referring to FIGS. 2 and 4, the mother substrate 11 for the display panel may include a first substrate S1, display structures DP, sealing members SLM, a second substrate S2, first support members SM1, and second support members SM2.

The first substrate S1 may further include a third peripheral area SA3 adjacent to the first panel area PA1 in the third direction D3. The third peripheral area SA3 may extend in the second direction D2, and may be adjacent to the first panel areas PA1 and the first peripheral area SA1 in the third direction D3.

Similarly, the second substrate S2 may further include a fourth peripheral area SA4 adjacent to the second panel area PA2 in the third direction D3. The fourth peripheral area SA4 may extend in the second direction D2, and may be adjacent to the second panel areas PA2 and the second peripheral area SA2 in the third direction D3.

The third peripheral area SA3 and the fourth peripheral area SA4 may overlap each other in a plan view. Unlike the mother substrate 10 for the display panel of FIG. 1, the third peripheral area SA3 and the fourth peripheral area SA4of the mother substrate 11 for the display panel of FIG. 4 may have substantially the same area as each other.

However, embodiments are not limited thereto, and the first substrate S1 may further include the third peripheral area SA3 in a direction opposite to the third direction D3, and the second substrate S2 may further include the fourth peripheral area SA4 in the direction opposite to the third direction D3.

The second support members SM2 may be disposed on the second surface S1b of the first substrate S1. The second support members SM2 may overlap the third peripheral area SA3 of the first substrate S1 in a plan view. The second support members SM2 overlapping the third peripheral area SA3 may be spaced apart from each other in a plan view. Accordingly, cutting the first substrate S1 may be easy. However, embodiments are not limited thereto, and one second support member SM2 may be positioned in the third peripheral area SA3 and may extend in the second direction D2.

The second support member SM2 positioned in the third peripheral area SA3 may be spaced apart from the first support member SM1 in the third direction D3. A length L2 of the first support member SM1 in the third direction D3 may be greater than a length L6 of the second support member SM2 in the third direction D3. When the length L2 of the first substrate S1 in the third direction D3 is smaller than the length L6 of the second support member SM2 in the third direction D3, an area of the mother substrate 11 for the display panel used to form the display panel may be reduced, and a removed area may be increased. Accordingly, manufacturing efficiency of the display panel may be decreased.

In an embodiment, when the display panel is formed, a panel area (e.g., the first panel area PA1 and the second panel area PA2 of FIGS. 2 and 4) and a peripheral area (e.g., the first peripheral area SA1, the second peripheral area SA2 of FIG. 2, and the first peripheral area SA1 and the third peripheral area SA3 of FIG. 4) may be disposed differently and the areas of each of the panel areas and the peripheral areas may vary.

Accordingly, in an embodiment, in consideration of the preset area of the display panel, when a length of the display panel in the second direction D2 is greater than a length of the mother substrate 11 for the display panel in the second direction D2, a peripheral area may be defined in the second direction D2 from the first panel area PA1 (e.g., the mother substrate 10 for the display panel of FIG. 1). In an embodiment, in consideration of the preset area of the display panel, when a length of the mother substrate 11 for the display panel in the third direction D3 is greater than a length of the mother substrate 11 for the display panel in the third direction D3, a peripheral area may be defined in the third direction D3 from the first panel area PA1 (e.g., the mother substrate 11 for the display panel of FIG. 4).

In an embodiment, the first substrate S1 may be cut between the first panel area PA1 and the third peripheral area SA3 adjacent to the first panel area PA1, and the second substrate S2 may be cut between the second panel area PA2 and the third peripheral area SA3 adjacent to the second panel area PA2. Due to the first support member SM1 and the second support member SM2, sagging in portions of the first substrate S1 and the second substrate S2 sag may not occur. The first support member SM1 and the second support member SM2 may prevent chipping, where cut edge portions of the first substrate S1 and the second substrate S2 may be broken or stamped.

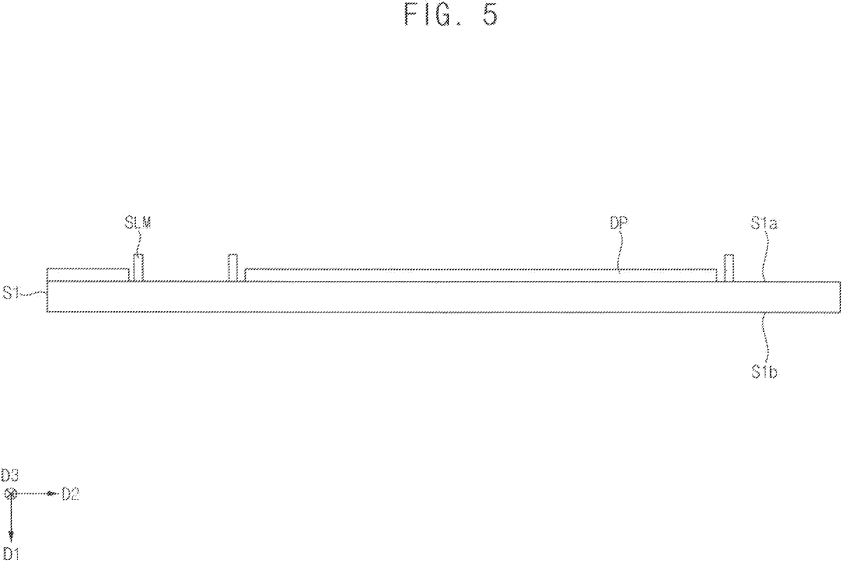

FIGS. 5 to 10 are schematic cross-sectional views illustrating a method of manufacturing a display panel according to an embodiment. For example, FIGS. 5 to 10 may be a method of manufacturing a display panel using the mother substrate 10 for the display panel of FIG. 1.

Referring to FIG. 5, in the method of manufacturing the display panel, display structures DP may be formed on a first surface S1a of a first substrate S1. Sealing members SLM may be formed on the first surface S1a of the first substrate S1.

The first substrate S1 may include the first panel areas PA1 and first peripheral areas SA1 surrounding at least one side of each of the first panel areas PA1. The display structures DP may be formed on the first substrate S1 to overlap the first panel areas PA1 in a plan view, respectively. The sealing members SLM may be disposed on the first substrate S1 and may overlap the first panel areas PA1 in a plan view.

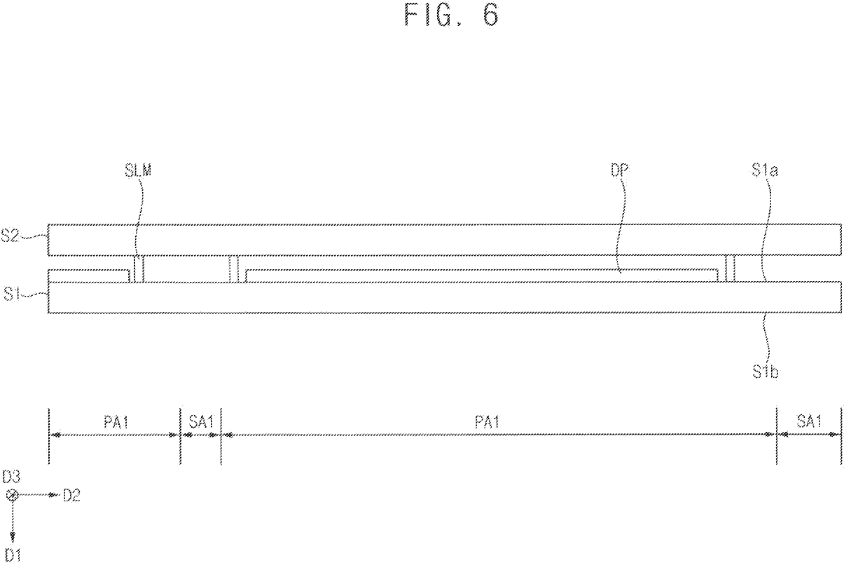

Referring to FIG. 6, in the method of manufacturing the display panel, a second substrate S2 may be formed on the display structures DP and the sealing members SLM on the first substrate S1. The first substrate S1 and the second substrate S2 may be bonded to each other through the sealing members SLM. The second substrate S2 may cover the display structures DP.

The second substrate S2 may include the second panel areas PA2 and the second peripheral areas SA2 surrounding at least one side of each of the second panel areas PA2. The second panel area PA2 of the second substrate S2 may overlap the first panel area PA1 of the first substrate S1 in a plan view, and the second peripheral area SA2 of the second substrate S2 may overlap the first peripheral area SA1 of the first substrate S1 in a plan view. Accordingly, the display structures DP may overlap the second panel areas PA2, in a plan view respectively.

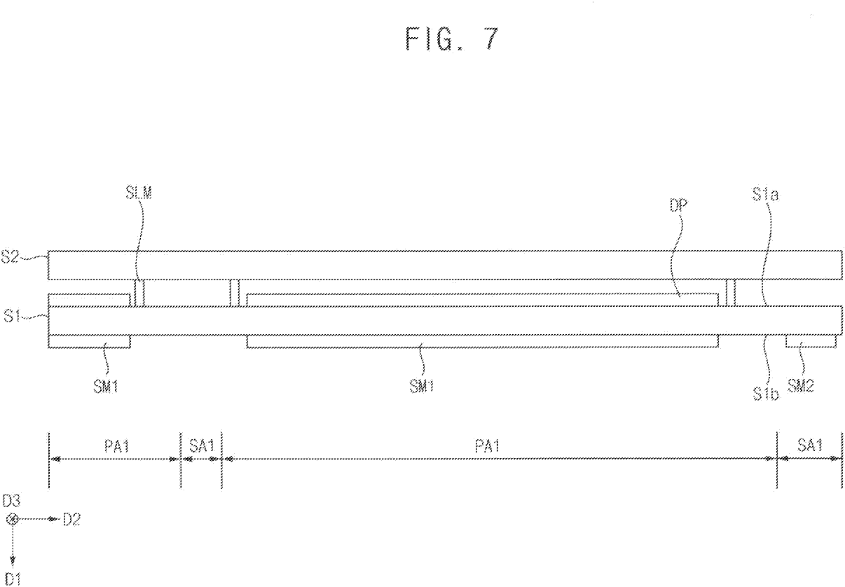

Referring to FIG. 7, in the method of manufacturing the display panel, first support members SM1 may be formed on a second surface S1b of the first substrate S1. The second surface S1b may be opposite to the first surface S1a in a first direction D1. The first support member SM1 may be formed to overlap the first panel area PA1 of the first substrate S1 in a plan view. Accordingly, the first support member SM1 may be formed to overlap the display structure DP in a plan view.

A second support member SM2 may be formed on the second surface S1b of the first substrate S1. The second support member SM2 may be formed to overlap, in a plan view, the first peripheral area SA1 positioned at the end of the first substrate S1. Accordingly, the second support member SM2 may be formed to be spaced apart from the display structure DP.

The first support member SM1 and the second support member SM2 may be formed substantially simultaneously. The first support member SM1 and the second support member SM2 may be formed in a same process. The first support member SM1 and the second support member SM2 may be formed of a reflective material. Accordingly, the first support member SM1 may prevent light emitted from the display structure DP from being emitted in the first direction D1.

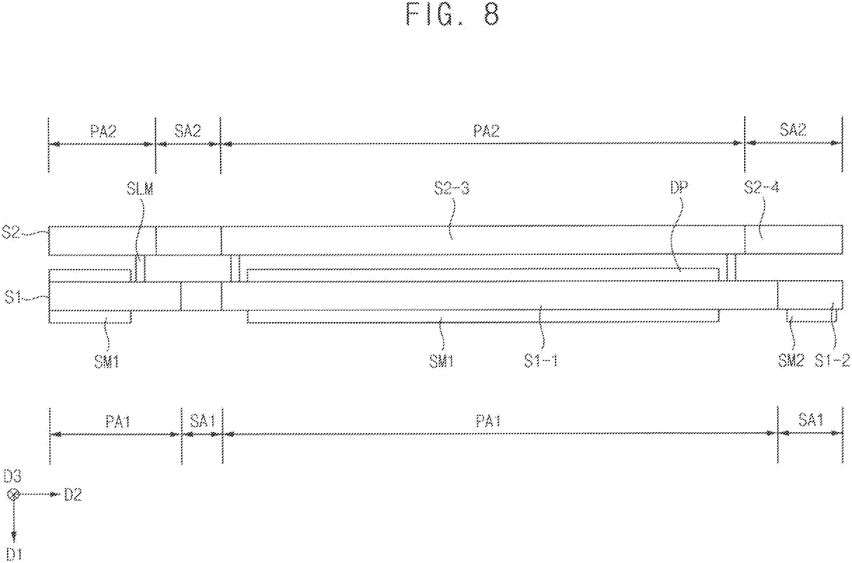

Referring to FIG. 8, in the method of manufacturing the display panel, the first substrate S1 may be cut along a boundary between the first panel area PA1 and the first peripheral area SA1 of the first substrate S1. For example, the first substrate S1 may be cut between a first portion S1-1 overlapping the first support member SM1 in a plan view of the first substrate S1, and a second portion S1-2 overlapping the second support member SM2 in a plan view of the first substrate S1. The first substrate S1 may be cut along a boundary between the first panel area PA1 and the first peripheral area SA1 disposed between the first panel areas PA1 in a plan view.

In the method of manufacturing the display panel, the second substrate S2 may be cut along a boundary between the second panel area PA2 and the second peripheral area SA2 of the second substrate S2. For example, the second substrate S2 may be cut between a third portion S2-3 overlapping the first support member SM1 in a plan view of the second substrate S2, and a fourth portion S2-4 overlapping the second support member S2 in a plan view of the second substrate S2. The second substrate S2 may be cut along a boundary between the second panel area PA2 and the second peripheral area SA2 disposed between the second panel areas PA2 in a plan view.

A driving chip or a flexible circuit board may be connected to the first panel area PA1 of the first substrate S1. Accordingly, an area of the first panel area PA1 may be larger than an area of the second panel area PA2 to expose an end of the first panel area PA1. The first substrate S1 and the second substrate S2 may be cut, respectively, so that an area of the first panel area PA1 is larger than an area of the second panel area PA2.

The cutting of the first substrate S1 and the second substrate S2 may be performed using a cutting knife, a cutting wheel, a laser, or the like. The cutting of each of the first substrate S1 and the second substrate S2 may be performed simultaneously or separately.

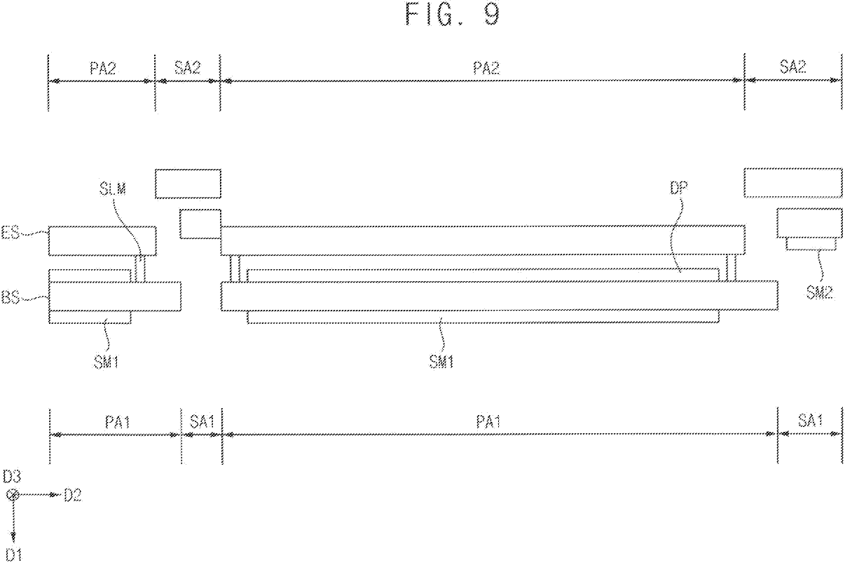

Referring to FIG. 9, in the method of manufacturing the display panel, a portion of the first substrate S1 positioned in the first peripheral area SA1 along the cut line may be removed. Similarly, a portion of the second substrate S2 positioned in the second peripheral area SA2 along the cut line may be removed. By removing a portion of the first substrate S1 that overlaps the first peripheral area SA1 in a plan view, the second support member SM2 overlapping the first peripheral area SA1 in a plan view and formed on the second surface S1b of the first substrate S1 may be also removed.

Referring to FIG. 10, base substrates BS may be formed from the first substrate S1, and encapsulation substrates ES may be formed from the second substrate S2. The base substrate BS, the encapsulation substrate ES, the display structure DP, the sealing member SLM, and the first support member SM1 may form a display panel.

In an embodiment, the first substrate S1 may be cut between the first panel area PA1 and the first peripheral area SA1 adjacent to the first panel area PA1. The second substrate S2 may be cut between the second panel area PA2 and the second peripheral area SA2 adjacent to the second panel area PA2. When the mother substrate 10 for the display panel is cut, the first support member SM1 may support a portion of the first substrate S1 positioned in the first panel area PA1. The second support member SM2 may support a portion of the first substrate S1 positioned in the first peripheral area SA1. Accordingly, a constant pressure may be applied to the entire mother substrate 10 for the display panel. The first support member SM1 and the second support member SM2 may prevent chipping, where cut edge portions of the first substrate S1 and the second substrate S2 may be broken or stamped, from occurring.

The mother substrate for the display panel and the method according to the embodiments may be applied to a display device included in a computer, a notebook, a mobile phone, a smartphone, a smart pad, a PMP, a PDA, an MP3 player, or the like.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A mother substrate for display panel, the mother substrate comprising:
a first substrate including:
a panel area; and
a peripheral area surrounding at least one side of the panel area;
a second substrate disposed on a first surface of the first substrate;
a first support member disposed on a second surface of the first substrate opposite to the first surface of the first substrate in a first direction, the first support member overlapping the panel area of the first substrate in a plan view; and
a second support member disposed on the second surface of the first substrate, the second support member overlapping the peripheral area of the first substrate in a plan view.

2. The mother substrate of claim 1, wherein the first support member and the second support member include a same material.

3. The mother substrate of claim 2, wherein the first support member and the second support member include a reflective material.

4. The mother substrate of claim 1, further comprising:
a display structure disposed between the first substrate and the second substrate, the display structure overlapping the panel area in a plan view.

5. The mother substrate of claim 4, wherein the first support member overlaps the display structure on the first substrate in a plan view.

6. The mother substrate of claim 4, wherein the second support member does not overlap the display structure on the first substrate in a plan view.

7. The mother substrate of claim 4, wherein a length of the first support member in a second direction that intersects the first direction is greater than or substantially equal to a length of the display structure in the second direction.

8. The mother substrate of claim 4, wherein the second support member is spaced apart from the first support member in a second direction that intersects the first direction.

9. The mother substrate of claim 8, wherein a length of the first support member in the second direction is greater than a length of the second support member in the second direction.

10. The mother substrate of claim 1, wherein a thickness of the first support member in the first direction is smaller than a thickness of the first substrate in the first direction.

11. The mother substrate of claim 1, wherein a thickness of the first support member in the first direction is substantially equal to a thickness of the second support member in the first direction.

12. A method of manufacturing a display panel, the method comprising:
forming a second substrate on a first surface of a first substrate, the first substrate including a first panel area and a first peripheral area surrounding at least one side of the first panel area, and the second substrate including a second panel area and a second peripheral area surrounding at least one side of the second panel area;
forming a first support member on a second surface of the first substrate opposite to the first surface of the first substrate in a first direction, the first support member overlapping the first panel area of the first substrate in a plan view;
forming a second support member on the second surface of the first substrate, the second support member overlapping the first peripheral area of the first substrate in a plan view;
cutting the first substrate along a boundary between the first panel area and the first peripheral area;
cutting the second substrate along a boundary between the second panel area and the second peripheral area; and
removing a portion of the first substrate and a portion of the second substrate, the removed portion of first substrate being disposed in the first peripheral area, and the removed portion of the second substrate being disposed in the second peripheral area.

13. The method of claim 12, wherein the first support member and the second support member are formed simultaneously.

14. The method of claim 12, wherein the first support member and the second support member include a reflective material.

15. The method of claim 12, wherein the removing of the portion of the first substrate and the portion of the second substrate includes removing the second support member formed in the first peripheral area of the first substrate.

16. The method of claim 13, further comprising:
forming a display structure between the first substrate and the second substrate in the first panel area of the first substrate.

17. The method of claim 16, wherein the first support member that is formed on the second surface of the first substrate overlaps the display structure in a plan view.

18. The method of claim 16, wherein the second support member that is formed on the second surface of the first substrate is spaced apart from the display structure in a plan view.

19. The method of claim 12, wherein
the cutting of the first substrate includes cutting between a first portion of the first substrate overlapping the first support member and a second portion of the first substrate overlapping the second support member in a plan view, and
the cutting of the second substrate includes cutting between a third portion of the second substrate overlapping the first support member in a plan view and a fourth portion of the second substrate overlapping the second support member in a plan view.

20. The method of claim 12, wherein
the first panel area overlaps the second panel area in a plan view, and
the first substrate and the second substrate are respectively cut so that an area of the first panel area is greater than an area of the second panel area.
